(19) United States
(12) Patent Application Publication
(10) Pub. No.: US 2006/0273332 A1
(43) Pub. Date: Dec. 7, 2006

(54) Nitride semiconductor light emitting device

(75) Inventors: Pil Geun Kang, Suwon (KR); Dong Min Jeon, Suwon (KR); Bong Il Yi, Suwon (KR); Tae Sung Jang, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/435,892

(22) Filed: May 18, 2006

(30) Foreign Application Priority Data
May 18, 2005 (KR) 10-2005-0041406

(51) Int. Cl. H01L 33/00

(52) U.S. Cl. 257/91

(57) ABSTRACT

The present invention relates to a nitride semiconductor light emitting device. The nitride semiconductor light emitting device includes a substrate; an n-type nitride semiconductor layer that is formed on the substrate; an active layer that is formed on the n-type nitride semiconductor layer; a p-type nitride semiconductor layer that is formed on the active layer; a transparent electrode that is formed on the p-type nitride semiconductor layer; a p-type bonding electrode that is formed to be connected on the transparent electrode; and an n-type electrode that is formed of a compound containing aluminum or silver and is formed on the n-type nitride semiconductor layer.

### CROSS-REFERENCE TO RELATED APPLICATIONS

The application claims the benefit of Korea Patent Application No. 2005-0041406 filed with the Korea Industrial Property Office on May 18, 2005, the disclosure of which is incorporated herein by reference.

### BACKGROUND OF THE INVENTION

1. Field of the Invention

The present invention relates to a nitride semiconductor light emitting device, and more specifically, to a nitride semiconductor light emitting device in which some of the light emitted from an active layer is prevented from being absorbed into an n-type electrode and disappearing to thereby enhance the light extraction efficiency of the nitride semiconductor light emitting device.

2. Description of the Related Art

In general, a nitride semiconductor having a relatively large energy band-gap (for example, a GaN semiconductor has about 3.4 eV) is actively used in a light emitting device for generating blue or green short-wavelength light. As such a nitride semiconductor, a material having a composition of AlₓIn_{y}Ga_{(1-x-y)}N (herein, 0≦x≦1, 0≦y≦1, and 0≦x+y≦1) is widely used.

However, since such a nitride semiconductor has a relatively large energy band-gap, it is difficult to form the ohmic contact with an electrode. Particularly, since an n-type nitride semiconductor layer has a larger energy band-gap, the contact resistance on the contact portion with an n-type electrode increases. Such an increase causes an operational voltage of the device to increase, thereby increasing the heating value. Further, the n-type electrode of the nitride semiconductor light emitting device according to the related art is formed of Cr/Au whose reflectance is low. Therefore, all light emitted from an active layer is not reflected, and some light is absorbed, thereby deteriorating the light extraction efficiency.

Hereinafter, the problems of the nitride semiconductor light emitting device according to the related art will be described in detail with reference to FIG. 1.

FIG. 1 is a cross-sectional view illustrating the structure of the nitride semiconductor light emitting device according to the related art.

As shown in FIG. 1, the nitride semiconductor light emitting device according to the related art is composed of a sapphire substrate 110, a GaN buffer layer (not shown), an n-type nitride semiconductor layer 120, an active layer 130, and a p-type nitride semiconductor layer 140, which are sequentially crystal-grown. The portions of the active layer 130 and p-type nitride semiconductor layer 140 are removed by etching, thereby forming a groove 170 on which a portion of the n-type nitride semiconductor layer 120 is exposed.

On the n-type nitride semiconductor layer 120 exposed on the bottom surface of the groove 170, an n-type electrode 200 is formed of Cr/Au. On the p-type nitride semiconductor layer 140, a transparent electrode 150 is formed of an ITO or the like. On a portion of the transparent electrode 150, a p-type bonding electrode 160 is formed.

Such a nitride semiconductor light emitting device operates as follows.

A hole injected through the p-type bonding electrode 160 extends transversely from the p-type bonding electrode 160 and is then injected from the p-type nitride semiconductor layer 140 into the active layer 130. An electron injected through the n-type electrode 200 is injected from the n-type nitride semiconductor layer 120 into the active layer 130. In the active layer 130, the hole and electron are recombined to thereby emit light. The emitted light is discharged outside the nitride semiconductor light emitting device through the transparent electrode 150.

At this time, the light ‘hv’ generated in the active layer 130 is discharged in all directions. FIG. 1 shows the discharge direction of a photon with \textcircled{1}, \textcircled{2}, and \textcircled{3}, for convenience. The lights moving in the directions of \textcircled{1} and \textcircled{2} are discharged outside the nitride semiconductor light emitting device through the transparent electrode 150, thereby contributing to the intensity of the nitride semiconductor light emitting device.

However, the light moving in the direction of \textcircled{3} is absorbed into the n-type electrode 200 and then disappears. Such absorption of light deteriorates the light extraction efficiency to thereby reduce the brightness of the nitride semiconductor light emitting device. The light extraction efficiency means a ratio of light generated by the active layer to light discharged into the air from the nitride semiconductor light emitting device.

In other words, since the conventional n-type electrode formed of Cr/Au has low reflectance as described above, the light which is emitted from the active layer so as to be directed to the n-type electrode is absorbed and disappears. Accordingly, the light extraction efficiency is deteriorated, thereby reducing the brightness.

### SUMMARY OF THE INVENTION

An advantage of the present invention is that it provides a nitride semiconductor light emitting device in which an n-type electrode formed of a material having low ohmic contact resistance and having high reflectance is provided on an n-type nitride semiconductor layer, so that the heating value of the device is reduced to thereby enhance reliability and some of the light emitted from an active layer is prevented from being absorbed into the n-type electrode and disappearing to thereby enhance the light extraction efficiency.

Additional aspects and advantages of the present general inventive concept will be set forth in part in the description which follows and, in part, will be obvious from the description, or may be learned by practice of the general inventive concept.

According to an aspect of the invention, a nitride semiconductor light emitting device includes a substrate; an n-type nitride semiconductor layer that is formed on the substrate; an active layer that is formed on the n-type nitride semiconductor layer; a p-type nitride semiconductor layer that is formed on the active layer; a transparent electrode that is formed on the p-type nitride semiconductor layer; a p-type bonding electrode that is formed to be connected on the transparent electrode; and an n-type electrode that is formed of a compound containing aluminum or silver and is formed on the n-type nitride semiconductor layer.

Preferably, in the compound, at least one metallic additive is added, which is selected from a group composed of Cu, Si, W, Mo, Co, and Ni. Then, aluminum or silver forming the n-type electrode is prevented from being degraded by hill-rock occurring due to a thermal process, thereby maintaining the low ohmic contact resistance and high reflectance of aluminum or silver. Further, the compound layer forming the n-type electrode preferably has a thickness of 500 to 5000 Å.

The n-type electrode is composed of a double layer in which a degradation preventing layer is laminated on a compound layer containing aluminum or silver. Accordingly, the high-reflection n-type electrode formed of aluminum or silver which is weak in heat is more reliably prevented from being degraded by heat.

Preferably, the degradation preventing layer is formed of at least one heat-resisting metal selected from a group composed of Ti, Ni, Pt, Pd, and Rh, and the degradation preventing layer has a thickness of 50 to 500 Å.

The n-type electrode is preferably composed of a triple layer in which a compound layer containing aluminum or silver, a degradation preventing layer, and an oxidation resisting layer are sequentially laminated, which makes it possible to prevent the degradation preventing layer from being exposed to the air and oxidized.

Preferably, the oxidation layer is formed of at least one base metal selected from a group composed of Au, Pt, and Rh, and the oxidation layer has a thickness of 200 to 4000 Å.

As such, the n-type electrode according to the present invention is formed of a material having low ohmic contact resistance and high reflectance, that is, a compound containing aluminum or silver on the n-type nitride semiconductor layer. Accordingly, the heat value of the device is reduced to enhance the reliability, and some of the light emitted from the active layer is prevented from being absorbed into the n-type electrode and disappearing, thereby enhancing the light extraction efficiency of the device.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating the structure of a nitride semiconductor light emitting device according to the related art;

FIG. 2 is a cross-sectional view illustrating the structure of a nitride semiconductor light emitting device according to a first embodiment of the present invention;

FIG. 3 is a graph comparatively showing the ohmic contact (I-V curve) of the nitride semiconductor light emitting device shown in FIGS. 1 and 2;

FIG. 4 is a diagram comparatively showing the reflectance of the nitride semiconductor light emitting device shown in FIGS. 1 and 2;

FIG. 5 is a cross-sectional view illustrating the structure of a nitride semiconductor light emitting device according to a second embodiment of the invention;

FIG. 5 is diagram comparatively showing the reflectance of the nitride semiconductor light emitting device shown in FIGS. 2 and 5; and

FIG. 7 is a cross-sectional view illustrating the structure of a nitride semiconductor light emitting device according to a third embodiment of the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings so that the present invention can be easily embodied by a person with an ordinary skill in the art.

In the drawings, the thickness of each layer is enlarged in order to clearly illustrate various layers and regions. In the entire specification, the same reference numerals are attached to the same or similar components.

Hereinafter, a nitride semiconductor light emitting device according to an embodiment of the present invention will be described in detail with reference to the accompanying drawings.

### First Embodiment

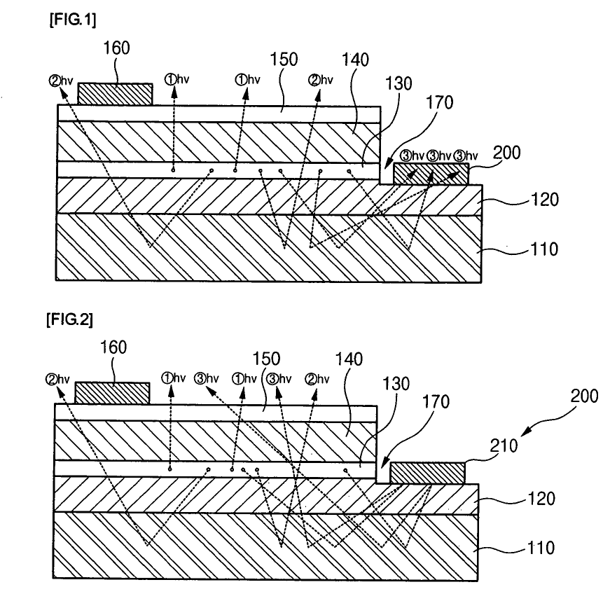

First, the nitride semiconductor light emitting device according to a first embodiment of the invention will be described in detail with reference to FIG. 2. FIG. 2 is a cross-sectional view illustrating the structure of the nitride semiconductor light emitting device according to the first embodiment of the invention.

As shown in FIG. 2, the nitride semiconductor light emitting device is composed of a buffer layer (not shown), a n-type nitride semiconductor layer 120, an active layer 130, and a p-type nitride semiconductor layer 140, which are sequentially laminated on a substrate 110.

Preferably, the substrate 110 is formed of a transparent material including sapphire. In addition to sapphire, the substrate 110 can be formed of a zinc oxide (ZnO), a gallium nitride (GaN), a silicon carbide (SiC), and an aluminum nitride (AIN).

The buffer layer (not shown) is formed of GaN and can be omitted.

The n-type and p-type nitride semiconductor layers 120 and 140 are formed of a GaN layer or GaN/AlGaN layer which is doped with a conductive impurity. The active layer 130 having a multi-quantum well structure is formed of an InGaN/GaN layer.

On the other hand, the active layer 130 can be formed of a quantum well layer or be formed to have a double-hetero structure. Further, it is determined by an amount of indium (In) contained in the active layer 130 whether a diode is a green light emitting device or blue light emitting device. More specifically, in the case of the blue light emitting device, the indium content is about 22%. In the case of the green light emitting device, the indium content is about 40%. In other words, an amount of indium which is used in forming the active layer 130 changes according to a required blue or green wavelength.

The portions of the active layer 130 and p-type nitride semiconductor layer 140 are removed by mesa etching. A groove 170 is accordingly formed, on which the n-type nitride semiconductor layer 120 is exposed.

On the p-type nitride semiconductor layer 140, a transparent electrode 50 is formed. In this case, if the transparent electrode 150 has high transmittance with respect to the emission wavelength of a light emitting device as well as a conductive metal oxide such as an ITO (indium tin oxide), the transparent electrode 150 can be also formed of a thin metallic film having high conductivity and low contact resistance.

When the transparent electrode 150 is formed of a thin metallic film, the thickness of the metallic film is preferably maintained to be less than 50 nm, in order to secure transmittance. For example, the metallic film can be formed to have a structure where a Ni layer having a thickness of 10 nm and a Au layer having a thickness of 40 nm are sequentially laminated.

On the transparent electrode 150 and the n-type nitride semiconductor layer 120 exposed on the bottom surface of the groove 170, a p-type bonding electrode 160 formed of Au and an n-type electrode 200 are respectively formed, the n-type electrode 200 serving to reflect light and functioning as an electrode.

Hereinafter, the n-type electrode 200 according to the first embodiment of the invention will be described in detail, the n-type electrode 200 serving to reflect light and functioning as an electrode.

The n-type electrode 200 according to the first embodiment of the invention is formed of a single layer which is a high-reflection n-type electrode 210 formed of a compound containing Al or Ag. As the compound, a compound to which at least one heat-resisting metallic additive selected from a group composed of Cu, Si, W, Mo, Co, and Ni is added is preferably used. This is because such a construction prevents aluminum or silver forming the high-reflection n-type electrode 210 from being degraded by a thermal process or the like.

In other words, aluminum or silver forming the high-reflection n-type electrode 210 is easily degraded by hill-rock occurring due to a thermal process. The degraded aluminum or silver cannot maintain low ohmic contact resistance and high reflectance which are unique characteristics thereof. In the high-reflection n-type electrode 210 according to the present embodiment, however, heat-resisting metallic additive is added to aluminum or silver to thereby prevent the degradation of aluminum or silver. Accordingly, the low ohmic contact resistance and high reflectance can be maintained.

Preferably, the high-reflection n-type electrode 210 has a thickness of 500 to 5000 Å. If the thickness thereof is less than 500 Å, the high-reflection n-type electrode 210 cannot have a reflection function. If the thickness thereof is larger than 5000 Å, stress is generated due to the large thickness of the electrode, thereby weakening the contact of the high-reflection n-type electrode 210.

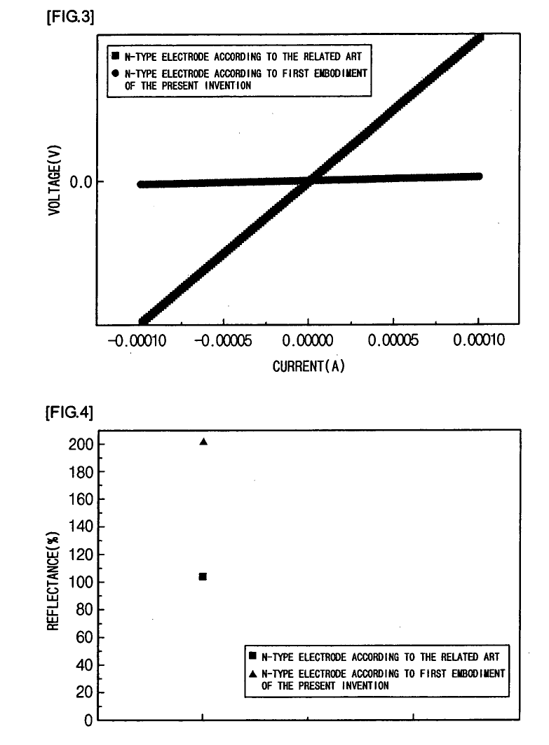

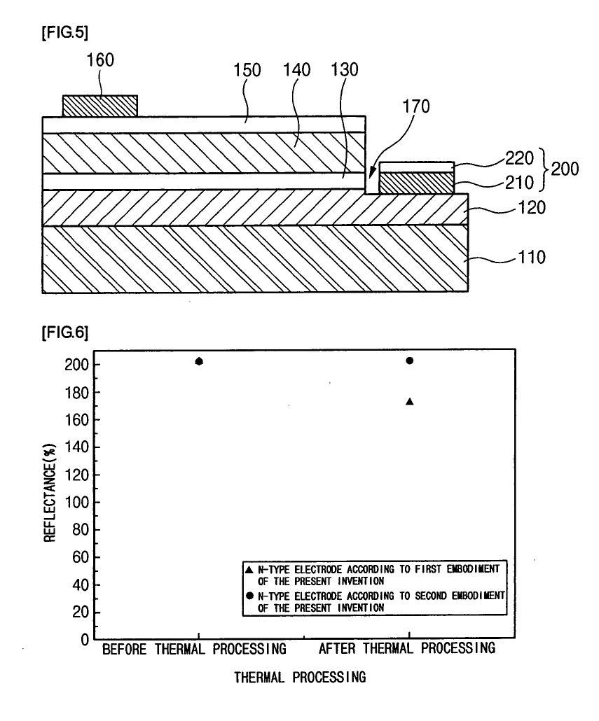

FIG. 3 is a graph comparatively showing the ohmic contact (I-V curve) of the nitride semiconductor light emitting device shown in FIGS. 1 and 2. FIG. 4 is a diagram comparatively showing the reflectance of the nitride semiconductor light emitting device shown in FIGS. 1 and 2.

Referring to FIG. 3, it can be found that the n-type electrode according to the first embodiment of the invention, which is composed of a single layer serving as a high-reflection n-type electrode formed of a compound containing aluminum or silver, has lower ohmic contact resistance than a conventional n-type electrode which is formed of Cr/Au.

Referring to FIG. 4, in the n-type electrode according to the first embodiment of the invention, which is composed of a single layer serving as a high-reflection n-type electrode formed of a compound containing aluminum or silver, the reflectance with respect to silicon (Si) is 202%. In the conventional n-type electrode which is formed of Cr/Au, the reflectance with respect to silicon (Si) is 104%. In other words, the reflectance of the n-type electrode according to the first embodiment of the invention increases by 94%, compared with that of the conventional n-type electrode. Therefore, light which is emitted from the active layer to be directed to the n-type electrode is all reflected so as to be again discharged into the transparent electrode, which makes it possible to enhance the light extraction efficiency of the light emitting device (refer to the direction \textcircled{3} of FIG. 2).

### Second Embodiment

A second embodiment of the present invention will be described with reference to FIG. 5. In the construction of the second embodiment, however, the descriptions of the same portions as the first embodiment will be omitted, and only the construction which is different from that of the first embodiment will be described in detail.

FIG. 5 is a cross-sectional view illustrating the structure of a nitride semiconductor light emitting device according to the second embodiment of the invention.

Although the construction of the nitride semiconductor light emitting device according to the second embodiment is almost the same as that of the nitride semiconductor light emitting device according to the first embodiment, there is a difference from the first embodiment in that the n-type electrode 200 is not composed of a single layer serving as the high-reflection n-type electrode 210 but composed of a double layer in which a degradation preventing layer 220 is laminated on the high-reflection n-type electrode 210, as shown in FIG. 5.

Therefore, in the second embodiment, the n-type electrode 200 also includes the high-reflection n-type electrode 210 formed of a compound containing aluminum or silver, which makes it possible to obtain the same effect as the first embodiment.

Further, since the degradation preventing layer 220 formed of heat-resisting metal is formed on the high-reflection n-type electrode 210, the high-reflection n-type electrode 210 formed of a compound containing aluminum or silver can be more reliably prevented from being degraded by a thermal process than in the first embodiment.

Preferably, the degradation preventing layer 220 is formed of at least one heat-resisting metal selected from a group composed of Ti, Ni, Pt, Pd, and Rh. Further, the degradation preventing layer 220 has a thickness of 50 to 500 Å. If the thickness thereof is less than 50 Å, the degradation preventing layer 220 cannot serve a role of preventing the degradation. If the thickness thereof is larger than 500 Å, stress is generated due to the large thickness, thereby weakening the contact of the degradation preventing layer 220.

FIG. 6 is a diagram comparatively showing the reflectance of the nitride semiconductor light emitting devices respectively shown in FIGS. 2 and 5. Referring to FIG. 6, the n-type electrode 200 including the degradation preventing layer 220 according to the second embodiment of the invention maintains the reflectance of about 202% after a thermal process, which is the same level of reflectance before a thermal process. On the contrary, the reflectance of the n-type electrode 200 according to the first embodiment, which does not include the degradation preventing layer 220, rapidly decreases from about 202% to about 172% after a thermal process.

Therefore, in the n-type electrode according to the second embodiment, the high-reflection n-type electrode is more reliably prevented from being degraded by a thermal process than in the n-type electrode according to the first embodiment, which makes it possible to maintain high reflectance.

### Third Embodiment

A third embodiment of the present invention will be described with reference to FIG. 5. Since the construction of the third embodiment is almost the same as that of the second embodiment, only the portion thereof which is different from the second embodiment will be described in detail.

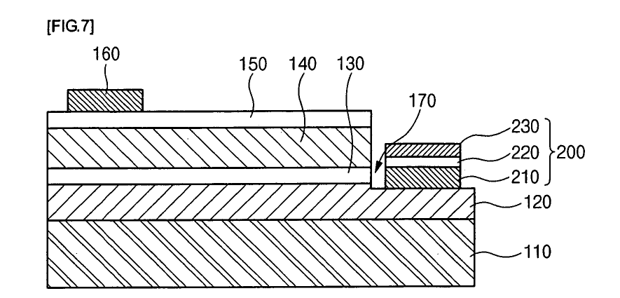

FIG. 7 is a cross-sectional view illustrating the structure of a nitride semiconductor light emitting device according to the third embodiment of the invention.

The construction of the nitride semiconductor light emitting device according to the third embodiment is almost the same as that of the nitride semiconductor light emitting device according to the second embodiment. As shown in FIG. 7, however, the n-type electrode 200 is composed of a triple layer in which the high-reflection n-type electrode 210, the degradation preventing layer 220, and an oxidation preventing layer 230 are sequentially laminated, different from the n-type electrode according to the second embodiment which is composed of a double layer in which the high-reflection n-type electrode 210 and the degradation preventing layer 220 are sequentially laminated.

Even in the third embodiment, the n-type electrode 200 also includes a double layer in which the high-reflection n-type electrode 210 and the degradation preventing layer 220 are sequentially laminated, which makes it possible to obtain the same effect as the second embodiment. Further, the degradation preventing layer 220 can be prevented from being exposed and oxidized by the oxidation preventing layer 230 formed on the degradation preventing layer 220.

Preferably, the oxidation preventing layer 230 is formed of at least one base metal selected from a group composed of Au, Pt, and Rh. Further, the oxidation preventing layer 230 has a thickness of 200 to 4000 Å. If the thickness thereof is less than 200 Å, the oxidation preventing layer cannot serve a role of preventing the oxidation. If the thickness thereof is larger than 4000 Å, stress is generated due to the large thickness, thereby weakening the contact of the oxidation preventing layer 230.

While the present invention has been described with reference to exemplary embodiments thereof, it will be understood by those skilled in the art that various changes and modifications in form and detail may be made therein without departing from the scope of the present invention as defined by the following claims.

As described above, the n-type electrode formed of a material having low ohmic contact resistance and high reflectance is provided on the n-type nitride semiconductor layer. Accordingly, the heating value of the device can be reduced to thereby enhance the reliability thereof, and some of the light emitted from the active layer can be prevented from being absorbed into the n-type electrode and disappearing to thereby enhance the light extraction efficiency.

Accordingly, in the present invention, the brightness, characteristic, and reliability of the nitride semiconductor light emitting device can be enhanced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride semiconductor light emitting device comprising:
a substrate;
an n-type nitride semiconductor layer that is formed on the substrate;
an active layer that is formed on the n-type nitride semiconductor layer;
a p-type nitride semiconductor layer that is formed on the active layer;
a transparent electrode that is formed on the p-type nitride semiconductor layer;
a p-type bonding electrode that is formed to be connected on the transparent electrode; and
an n-type electrode that is formed of a compound containing aluminum or silver and is formed on the n-type nitride semiconductor layer.

2. The nitride semiconductor light emitting device according to claim 1,
wherein, in the compound, at least one metallic additive is added, which is selected from a group composed of Cu, Si, W, Mo, Co, and Ni.

3. The nitride semiconductor light emitting device according to claim 1,
wherein the n-type electrode has a thickness of 500 to 5000 Å.

4. The nitride semiconductor light emitting device according to claim 1 further including a buffer layer in the interface between the substrate and the n-type nitride semiconductor layer.

5. The nitride semiconductor light emitting device according to claim 1,
wherein the n-type electrode is composed of a double layer in which a degradation preventing layer is laminated on a compound layer containing aluminum or silver.

6. The nitride semiconductor light emitting device according to claim 5,
wherein the degradation preventing layer is formed of at least one heat-resisting metal selected from a group composed of Ti, Ni, Pt, Pd, and Rh.

7. The nitride semiconductor light emitting device according to claim 5,
wherein the degradation preventing layer has a thickness of 50 to 500 Å.

8. The nitride semiconductor light emitting device according to claim 1,
wherein the n-type electrode is composed of a triple layer in which a compound layer containing aluminum or silver, a degradation preventing layer, and an oxidation resisting layer are sequentially laminated.

9. The nitride semiconductor light emitting device according to claim 8,
wherein the oxidation layer is formed of at least one base metal selected from a group composed of Au, Pt, and Rh.

10. The nitride semiconductor light emitting device according to claim 8,
wherein the oxidation layer has a thickness of 200 to 4000 Å.
